(19) United States
(12) Patent Application Publication
(10) Pub. No.: US 2009/0129185 A1
(43) Pub. Date: May 21, 2009

(54) SEMICONDUCTOR CIRCUITS CAPABLE OF SELF DETECTING DEFECTS

(76) Inventors: John J. Cassels, Marlboro, NY (US); Jonathan Robert Fales, South Burlington, VT (US); Muthukumarasamy Karthikeyan, Fishkill, NY (US); Thomas Martin Maffitt, Bulington, VT (US)

Correspondence Address: SCHMEISER, OLSEN & WATTS, 22 CENTURY HILL DRIVE, SUITE 302, LATHAM, NY, 12110, US

(21) Appl. No.: 11/941,996

(22) Filed: Nov. 19, 2007

(51) Int. Cl. G11C 29/04

(52) U.S. Cl. 365/201

(57) ABSTRACT

A digital circuit and a method for operating the same. The digital circuit includes (a) M×N regular cells electrically arranged in M rows and N columns, (b) N reference cells corresponding one-to-one to the N columns, and (c) N comparing circuits corresponding one-to-one to the N columns. Each regular cell is electrically coupled to a comparing circuit. Each reference cell is electrically coupled to the associated comparing circuit. Each regular cell includes a first tap node. Each reference cell includes P tap nodes. If a first voltage of the first tap node of a regular cell is between two voltages of two tap nodes of the P tap nodes of the associated reference cell, then the associated comparing circuit is capable of generating a first signal. If the first voltage is not between the two voltages, then the associated comparing circuit is capable of generating a second signal.

### FIELD OF THE INVENTION

The present invention relates generally to semiconductor circuits and more particularly to semiconductor circuits capable of self detecting their own defects.

### BACKGROUND OF THE INVENTION

Conventional semiconductor circuits may have defects. Therefore, it is necessary to test the semiconductor circuits for those defects. As a result, there is a need for a semiconductor circuit (and a method for operating the same) that is capable of self testing.

### SUMMARY OF THE INVENTION

The present invention provides a digital circuit operation method, comprising providing (a) M×N regular cells electrically arranged in M rows and N columns, M and N being positive integers, (b) N reference cells corresponding one-to-one to the N columns, and (c) N comparing circuits corresponding one-to-one to the N columns, wherein each regular cell of the M×N regular cells is electrically coupled to a comparing circuit of the N comparing circuits associated with a column in which the regular cell resides, wherein each reference cell of the N reference cells is electrically coupled to the associated comparing circuit of the N comparing circuits, wherein each regular cell of the M×N regular cells comprises a first tap node, and wherein each reference cell of the N reference cells comprises P tap nodes, P being an integer greater than 1; selecting a regular cell of the M×N regular cells for testing; using a comparing circuit associated with the regular cell, in response to a first voltage of the first tap node of the regular cell being between two voltages of two tap nodes of the P tap nodes of the associated reference cell, to generate a first signal indicating that the regular cell is in good condition; and using the comparing circuit associated with the regular cell, in response to the first voltage of the first tap node of the regular cell not being between the two voltages of the two tap nodes of the P tap nodes of the associated reference cell, to generate a second signal indicating that the regular cell is not in good condition.

The present invention provides a semiconductor circuit (and a method for operating the same) that is capable of self testing.

### BRIEF DESCRIPTION OF THE DRAWINGS

FIG. 1 shows a digital circuit, in accordance with embodiments of the present invention.

FIG. 2 shows another digital circuit, in accordance with embodiments of the present invention.

FIG. 2A shows one embodiment of a MUX circuit of FIG. 2.

FIG. 3 shows a comparator as one embodiment of comparators of comparing circuits of FIGS. 1 and 2, in accordance with embodiments of the present invention.

### DETAILED DESCRIPTION OF THE INVENTION

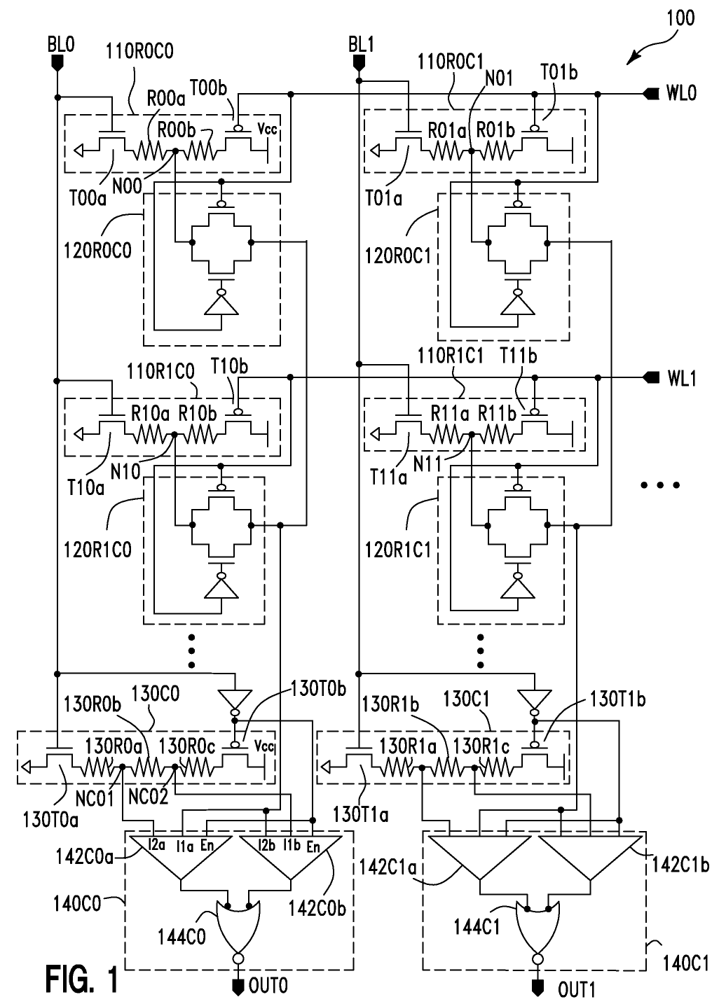

FIG. 1 shows a digital circuit 100, in accordance with embodiments of the present invention. More specifically, the digital circuit 100 comprises four regular cells 110R0C0, 110R0C1, 110R1C0, and 110R1C1 (also collectively referred to as regular cells 110) arranged in two rows and two columns. The digital circuit 100 further comprises four pass gate circuits 120R0C0, 120R0C1, 120R1C0, and 120R1C1 corresponding to the four regular cells 110R0C0, 110R0C1, 110R1C0, and 110R1C1, respectively.

In one embodiment, the digital circuit 100 further comprises two reference cells 130C0 and 130C1 corresponding to the two columns of the regular cells 110. More specifically, the reference cell 130C0 corresponds to the regular cells 110R0C0 and 110R1C0, whereas the reference cell 130C1 corresponds to the regular cells 110R0C1 and 110R1C1. The digital circuit 100 further comprises two comparing circuits 140C0 and 140C1 corresponding to the reference cells 130C0 and 130C1, respectively.

In one embodiment, the regular cell 110R0C0 comprises resistors R00a and R00b coupled together in series and coupled to Vcc and ground through a PFET (p-channel field effect transistor) T00b and an NFET (n-channel field effect transistor) T00a as shown in FIG. 1. The structures of the regular cells 110R0C1, 110R1C0, and 110R1C1 are similar to the structure of the regular cell 110R0C0.

With reference to the regular cell 110R0C0, in one embodiment, a tap node N00 of the two resistors R00a and R00b is electrically connected to the comparing circuit 140C0 through the pass gate circuit 120R0C0. More specifically, the tap node N00 is electrically connected to (i) an input I1a of a comparator 142C0a of the comparing circuit 140C0 and (ii) an input I2b of a comparator 142C0b of the comparing circuit 140C0. Similarly, tap nodes N01, N10, and N11 of the regular cells 110R0C1, 110R1C0, and 110R1C1, respectively, are electrically connected to the corresponding comparing circuits 140C0 and 140C1 in a manner similar to the manner in which the tap node N00 of the regular cell 110R0C0 is electrically connected to the comparing circuit 140C0.

In one embodiment, the reference cell 130C0 comprises resistors 130R0a, 130R0b, and 130R0c coupled together in series and coupled to Vcc and ground through a PFET 130T0b and a NFET 130T0a, respectively, as shown in FIG. 1. A tap node NC01 of two resistors 130R0a and 130R0b is electrically connected to an input I2a of the comparator 142C0a of the comparing circuit 140C0. A tap node NC02 of two resistors 130R0b and 130R0c is electrically connected to an input I1b of the comparator 142C0b of the comparing circuit 140C0. The structure of the reference cell 130C1 is similar to the structure of the reference cell 130C0. Tap nodes of the reference cell 130C1 are electrically connected to the comparators 142C1a and 142C1b of the comparing circuit 140C1 in a manner similar to the manner in which the tap nodes NC01 and NC02 of the reference cell 130C0 are electrically connected to the comparators 142C0a and 142C0b of the comparing circuit 140C0.

In one embodiment, the resistors R00a and R00b of the regular cell 110R0C0 are two adjacent segments of a single regular metal line R00a+R00b in an interconnect layer (not shown) of an integrated circuit (not shown). Similarly, the resistors R10a and R10b of the regular cell 110R1C0, the resistors R01a and R01b of the regular cell 110R0C1, and the resistors R11a and R11b of the regular cell 110R1C1 can be adjacent segments of single regular metal lines R10a+R10b, R01a+R01b, and R11a+R11b, respectively.

In one embodiment, the resistors 130R0a, 130R0b, and 130R0c of the reference cell 130C0 are three adjacent segments of a single reference metal line 130R0a−130R0b+130R0c in an interconnect layer (not shown) of the integrated circuit. Similarly, the resistors 130R1a, 130R1b, and 130R1c of the reference cell 130C1 can be three adjacent segments of a single reference metal line 130R1a+130R1b+130R1c.

The digital circuit 100 is capable of testing the regular metal lines R00a+R00b, R10a+R10b, R01a+R01b, and R11a+R11b. For instance, if the regular metal line R00a+R00b is in good condition, then the output signal OUT0 of the comparing circuit 140C0 is pulled high. If the regular metal line R00a+R00b is not in good condition (e.g., open circuit), then the output signal OUT0 of the comparing circuit 140C0 is pulled low.

In one embodiment, the line testing operation of the digital circuit 100 is as follows. Assume that the regular metal line R00a+R00b is to be tested. Accordingly, a bitline BL0 is pulled high and a wordline WL0 is pulled low resulting in the regular metal line R00a+R00b being selected for testing, whereas a wordline WL1 is pulled high resulting in the regular metal line R10a+R10b not being selected for testing. More specifically, as a result of the bitline BL0 being high and the wordline WL0 being low, the NFET T00a and the PFET T00b are both turned on resulting in the regular metal line R00a+R00b being connected to ground and Vcc. Also as a result of the bitline BL0 being high and the wordline WL0 being low, the pass gate circuit 120R0C0 is turned on resulting in the tap node N00 being electrically connected to (i) the input I1a of the comparator 142C0a of the comparing circuit 140C0 and (ii) the input I2b of the comparator 142C0b of the comparing circuit 140C0 through the pass gate circuit 120R0C0. Also as a result of the bitline BL0 being high, (i) the NFET 130T0a and the PFET I 30T0b are both turned on resulting in the reference metal line 13OROa+13OR0b+130R0c being electrically connected to ground and Vcc and (ii) the comparators 142C0a and 142C0b are enabled.

With reference to the reference cell 130C0, assume further that (i) the tap nodes NC01 and NC02 are at locations such that the length ratio of the resistors 130R0a, 130R0b, and 130R0c is 1:8:1 and (ii) the cross-section area of the reference metal line 130R0a+130R0b+130ROc is the same along the length of the reference metal line 130R0a+130R0b+130R0c. As a result, the ratio of the resistances of the resistors 130R0a, 130R0b, and 130R0c is also 1:8:1. Assume further that the Vcc=10V. As a result, the voltage at the tap node NC02 V(NC02)<9V (voltage divider rule) resulting in V(I1b)=9V. Also as a result of Vcc=10V, V(NC01)=1V (voltage divider rule) resulting in V(I2a)=1 V.

Assume that the regular metal line R00a+R00b is in good condition (e.g., no open circuit). Assume further that (i) the tap node N00 is at middle point of the regular metal line R00a+R00b and (ii) the cross-section area of the regular metal line R00a+R00b is the same along the length of the regular metal line R00a+R00b. As a result, the ratio of the resistances of the resistors R00a and R00b is 5:5. As a result, V(N00)=5V resulting in the input I2b of the comparator 142C0b and the input I1a of the comparator 142C0a receiving the voltage of 5 volts from tap node N00 through the pass gate circuit 120R0C0. As a result of V(I1a)=5V and V(I2a)=1V, the output signal of the comparator 142C0a is pulled low, As a result of V(I1b)=9V and V(I2b)=5V, the output signal of the comparator 142C0b is pulled low. As a result of both the output signals of both the comparators 142C0a and 142C0b being low, the output signal OUT0 of the NOR gate 144C0 is pulled high. This indicates that the regular metal line R00a+R00b is in good condition.

Assume alternatively that the regular metal line R00a+R00b has an open circuit in the resistor R00a. As a result, V(N00)=10V (=Vcc) resulting in the input I2b of the comparator 142C0b and the input I1a of the comparator 142C0a receiving the voltage of 10 volts from tap node N00 through the pass gate circuit 120R0C0. As a result of V(I1a)=10V and V(I2a)=1V, the output signal of the comparator 142C0a is pulled low. As a result of V(I1b)=9V and V(I2b)=10V, the output signal of the comparator 142C0b is pulled high. As a result of the output signal of the comparator 142C0a being low and the output signal of the comparator 142C0b being high, the output signal OUT0 of the NOR gate 144C0 is pulled low. This indicates that the regular metal line R00a+R00b is not in good condition.

Assume alternatively that the regular metal line R00a+R00b has an open circuit in the resistor R00b. As a result, V(N00)=0V (the tap node N00 is connected to ground) resulting in the input I2b of the comparator 142C0b and the input I1a of the comparator 142C0a receiving the voltage of 0 volt from tap node N00 through the pass gate circuit 120R0C0. As a result of V(I1a)=0V and V(I2a)=1V, the output signal of the comparator 142C0a is pulled high. As a result of V(I1b) 9V and V(I2b)=0V, the output signal of the comparator 142C0b is pulled low. As a result of the output signal of the comparator 142C0a being high and the output signal of the comparator 142C0b being low, the output signal OUT0 of the NOR gate 144C0 is pulled low. This indicates that the regular metal line R00a+R00b is not in good condition.

In one embodiment, the regular metal lines R10a+R10b, R01a+R01b, or R11a+R11b can be tested in a manner similar to the manner in which the regular metal line R00a+R00b is tested. It should be noted that the metal lines of regular cells in a same row can be tested simultaneously. For instance, the regular metal lines R00a+R00b and R01a+R01b can be tested simultaneously. More specifically, the bitlines BL0 and BL1 are pulled high and the wordline WL0 is pulled low resulting in the regular metal lines R00a+R00b and R01a+R01b being selected for testing, whereas the wordline WL1 is pulled high resulting in the metal lines R10a+R10b and R11a+R11b are not selected for testing.

In summary, if V(N00) <V(NC01) or V(N00)>V(NC02) (i.e., V(N00) is not between V(NC01) and V(NC02)), then the output signal OUT0 of the comparing circuit 140C0 is pulled low indicating that the regular metal line R00a+R00b is not in good condition. If V(N00)>V(NC01) and V(N00)<V(NC02) (i.e., V(N00) is between V(NC01) and V(NC02)), then the output signal OUT0 of the comparing circuit 140C0 is pulled high and the regular metal line R00a+R00b can be considered being in good condition. In other words, the output signal OUT0 of the comparing circuit 140C0 indicates whether the selected regular metal line R00a+R00b is in good condition.

In one embodiment, the tap nodes N00, NC01, and NC02 are disposed such that V(N00) is between V(NC01) and V(CN02) in the case which the metal line R00a+R00b is in good condition. Accordingly, the tap nodes N00, NC01, and NC02 are disposed such that

$$\frac{L ( 130 R 0 b ) + L ( 130 R 0 c )}{L ( 130 R 0 a ) + L ( 130 R 0 b ) + L ( 130 R 0 c )} > \frac{L ( R 00 b )}{L ( R 00 a ) + L ( R 00 b )} > \frac{L ( 130 R 0 c )}{L ( 130 R 0 a ) + L ( 130 R 0 b ) + L ( 130 R 0 c )}$$

wherein L(R) represents the length of resistor R provided that the segments of the resistors 130R0a, 130R0b, 130R0c, R00a, and R00b are made of the same material.

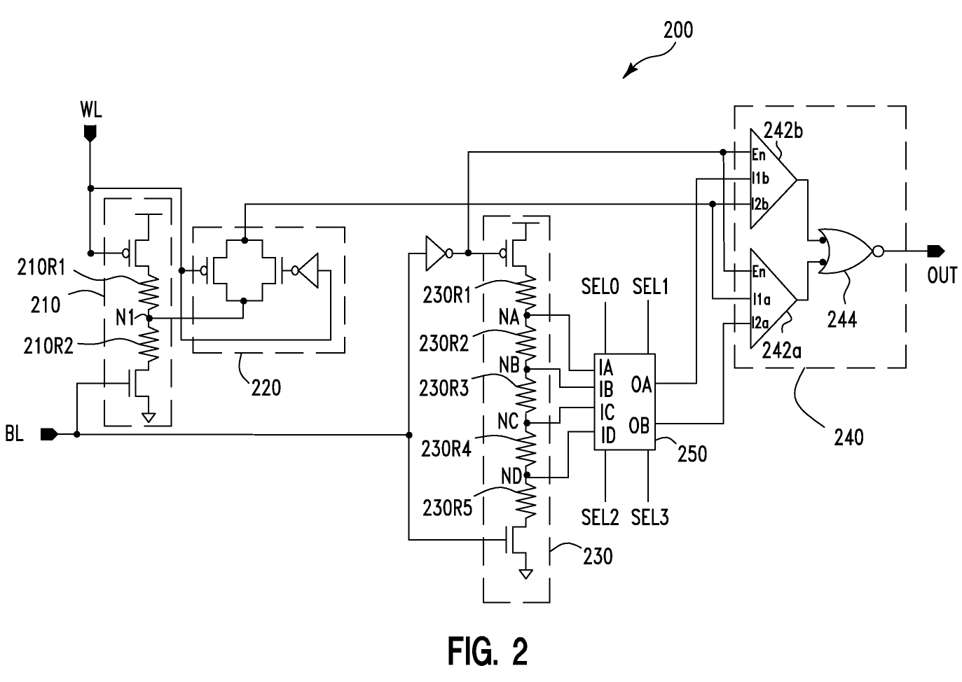

FIG. 2 shows a digital circuit 200, in accordance with embodiments of the present invention. More specifically, the digital circuit 200 is similar to a column of the digital circuit 100 of FIG. 1, except that (i) the digital circuit 200 further comprises a MUX circuit 250 and (ii) a reference cell 230 of the digital circuit 200 comprises five resistors 230R1, 230R2, 230R3, 230R4, and 230R5. These five resistors can be five adjacent segments of a single reference metal line 230R. It should be noted that the digital circuit 200 comprises multiple regular cells, but only one regular cell 210 is shown in FIG. 2 for simplicity.

In one embodiment, four tap nodes NA, NB, NC, and ND of the reference metal line 230R are electrically connected to four inputs IA, IB, IC, and ID of the MUX Circuit 250, respectively. Two outputs OA and OB of the MUX circuit 250 are electrically connected to an input I1b of a comparator 242b and an input I2a of a comparator 242a, respectively. Depending on four select signals SEL0-3 from the controller circuit, the outputs OA and OB of the MUX circuit 250 receive two of four input signals IA, IB, IC, and ID such that voltage of the output OA is higher than voltage of the output OB. There are six different combinations of the outputs OA and OB from the inputs IA-ID. More specifically, the outputs OA and OB can receive the signals of the inputs IA and IB, the inputs IA and IC, the inputs IA and ID, the inputs IB and IC, the inputs IB and ID, or the inputs IC and ID.

In one embodiment, the line testing operation of the digital circuit 200 is similar to the operation of the digital circuit 100 of FIG. 1. More specifically, the digital circuit 200 is capable of testing a regular metal line 21OR+210R2 of a regular cell 210. For instance, assume that the regular metal line 210R1+210R2 is to be tested. As a result, a bitline BL is pulled high and a wordline WL is pulled low resulting in the regular metal line 210R1+210R2 being selected for testing. More specifically, as a result of the bitline BL being high and the wordline WL being low, similar to the case of FIG. 1, a tap node N1 of the regular metal line 210R1+210R2 is electrically connected to (i) the input I1a of the comparator 242a of the comparing circuit 240 and (ii) the input I2b of the comparator 242b of the comparing circuit 240 through the pass gate circuit 220. Also as a result of the bitline BL being high, the comparators 242a and 242b are enabled in a manner similar to the case of FIG. 1.

Assume further that (i) the tap node N1 is at middle point of the regular metal line 210R1+210R2 and (ii) the cross-section area of the regular metal line 210R1+210R2 is the same along the length of the metal line 210R1+210R2. Assume that the regular metal line 210R1+210R2 is nearly broken at a certain point of the resistor 210R2 such that the ratio of the resistances of the resistors 210R1 and 210R2 is 2:8. Assume further that (i) the tap nodes NA, NB, NC, and ND are at locations such that the length ratio of the resistors 230R1, 120R2, 130R3, 230R4, and 230R5 is 1:2:4:2:1 and (ii) the cross-section area of the reference metal line 230R is the same along the length of the reference metal line 230R. As a result, the ratio of the resistances of the resistors 230R1, 120R2, 230R3, 230R4, and 230R5 is also 1:2:4:2:1. Assume further that the Vcc−10V. As a result, the voltages at the tap nodes NA, NB, NC, and ND are 9V, 7V, 3V, and 1V (voltage divider rule), respectively, resulting in the voltages of the inputs IA, IB IC, and ID of the MUX circuit 250 are 9V, 7V, 3V, and 1V, respectively.

Assume that the four select signals SEL0-3 of the MUX circuit 250 are such that the outputs OA and OB receive the signals from IB and IC, respectively (i.e., the tap nodes NB and NC are selected). As a result, V(I1b)=V(NB)−7V and V(I2a) V(IC)=3V.

As a result of ratio of the resistances of the resistors 210R1 and 210R2 being 2:8 and Vcc=10V, V(N1)−8V (voltage divider rule). Because V(N1) is not between the voltages of the selected tap nodes NB and NC (7V and 3V. respectively), the digital circuit 200 determines that the regular metal line 210R1+210R2 is not in good condition.

The digital circuit 200 of FIG. 2 is more sensitive than the digital circuit 100 of FIG. 1. More specifically, there are cases in which a regular metal line is nearly broken and is identified as not in good condition by the digital circuit 200 but is still identified as in good condition by the digital circuit 100. More specifically, in the instance described above, V(N1)=8V which is not between the voltages of the selected tap nodes NB and NC resulting in the digital circuit 200 determining that the regular metal line 210R1+210R2 is not in good condition. With reference to FIG. 1, in the instance described above, assume that V(N00)−8V. As a result, V(N00) is between V(NC01) and V(NC02) (1V and 9V, respectively) resulting in the digital circuit 100 determining that the regular metal line R00a+R00b is in good condition. This indicates that the digital circuit 100 is not as sensitive as the digital circuit 200.

FIG. 2A shows one embodiment of the MUX circuit 250 of FIG. 2. More specifically, the MUX circuit 250 comprises two multiplexers 252 and 254. The four inputs IA, IB, IC, and ID are electrically connected to (i) four inputs IA1, IB1, IC1, and ID1, respectively, of the multiplexer 252 and (ii) four inputs IA2, IB2, IC2, and ID2, respectively, of the multiplexer 254. The output OA is an output of the multiplexer 252 and the output OB is an output of the multiplexer 254. The select inputs SEL0 and SEL1 are select inputs of the multiplexer 252 and the select inputs SEL2 and SEL3 are select inputs of the multiplexer 254.

In one embodiment, the operation of the MUX circuit 250 is as follows. Depending on the two select signals SEL0 and SEL1, the output OA of the multiplexer 252 receives one of the four input signals IA1, IB1, IC1, and ID1 (i.e., one of the four input signals IA, IB, IC, and ID). Depending on the two select signals SEL2 and SEL3 from the controller circuit, the output OB of the multiplexer 254 receives one of the four input signals IA2, IB2, IC2, and ID2 (i.e., one of the four input signals IA, IB, IC, and ID. In one embodiment, the four select signals SEL0-SEL3 are such that V(OA)>V(OB).

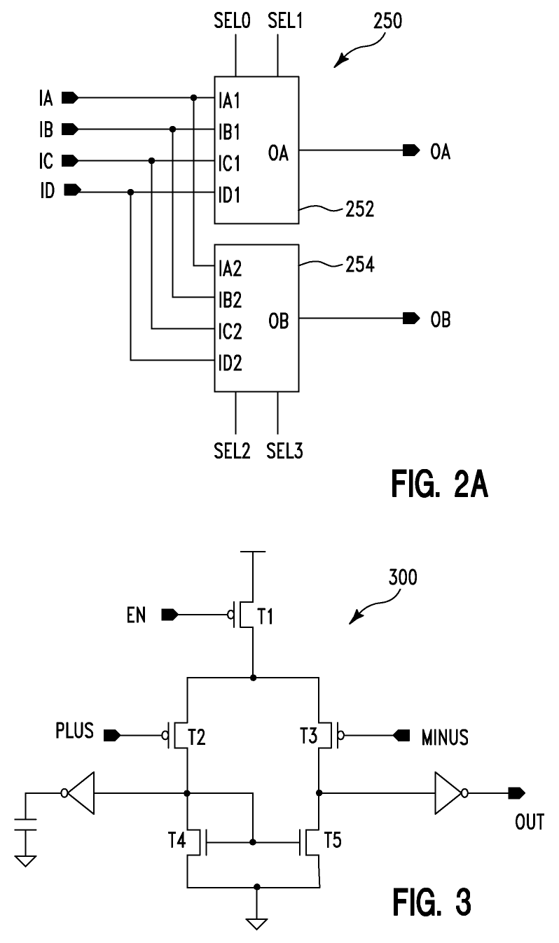

FIG. 3 shows a comparator 300 as one embodiment of the comparators 142C0a and 142C0b of the comparing circuit 140C0 of FIG. 1 and the comparators 242a and 242b of the comparing circuit 240 of FIG. 2, in accordance with embodiments of the present invention.

The operation of the comparator 300 is as follows. When EN signal is low, the comparator 300 is enabled. The output OUT of the comparator 300 is high when the input PLUS is higher than the input MINUS. The output OUT of the comparator 300 is low when the input PLUS is lower than the input MINUS.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A digital circuit, comprising:
(a) M×N regular cells electrically arranged in M rows and N columns, M and N being positive integers;
(b) N reference cells corresponding one-to-one to the N columns; and
(c) N comparing circuits corresponding one-to-one to the N columns,
wherein each regular cell of the M×N regular cells is electrically coupled to a comparing circuit of the N comparing circuits associated with a column in which the regular cell resides,
wherein each reference cell of the N reference cells is electrically coupled to the associated comparing circuit of the N comparing circuits,
wherein each regular cell of the M×N regular cells comprises a first tap node,
wherein each reference cell of the N reference cells comprises P tap nodes, P being an integer greater than 1,
wherein if a first voltage of the first tap node of a regular cell is between two voltages of two tap nodes of the P tap nodes of the associated reference cell, then the associated comparing circuit is configured to generate a first signal indicating that the regular cell is in good condition, and
wherein if the first voltage of the first tap node of a regular cell is not between the two voltages of the two tap nodes of the P tap nodes of the associated reference cell, then the associated comparing circuit is configured to generate second signal indicating that the regular cell is not in good condition.

2. The digital circuit of claim 1, further comprising M×N pass gate circuits corresponding one-to-one to the M×N regular cells,
wherein each pass gate circuit of the M×N pass gate circuits is configured to electrically couple the associated regular cell to the associated comparing circuit in response to the associated regular cell being selected for testing.

3. The digital circuit of claim 1, further comprising N MUX circuits corresponding one-to-one to the N columns,
wherein each MUX circuit of the N MUX circuits is electrically coupled to the P tap nodes of the associated reference cell, and
wherein each MUX circuit of the N MUX circuits is configured to electrically couple two tap nodes of the P tap nodes to the associated comparing circuit at a time.

4. The digital circuit of claim 1,
wherein each regular cell of the M×N regular cells comprises a first metal line,
wherein the first tap node of the each regular cell divides the first metal line into a first segment and a second segment,
wherein each reference cell of the N reference cells comprises a second metal line,
wherein P=2,
wherein the P tap nodes comprise a second tap node and a third tap node,
wherein the second and third tap nodes divide the second metal line into a third segment, a fourth segment, and a fifth segment,
wherein the fourth segment is disposed between the third segment and the fifth segment, and
wherein a first length L(R1), a second length L(R2), a third length L(R3), a fourth length L(R4), and a fifth length L(R5) of the first segment, the second segment, the third segment the fourth segment, and the fifth segment, respectively, are such that
$$\frac{L ( R 3 ) + L ( R 4 )}{L ( R 3 ) + L ( R 4 ) + L ( R 5 )} > \frac{L ( R 1 )}{L ( R 1 ) + ( R 2 )} > \frac{L ( R 3 )}{L ( R 3 ) + L ( R 4 ) + L ( R 5 )} .$$

5. The digital circuit of claim 4,
wherein the first metal line of the each regular cell is electrically coupled to a power supply through a first NFET (n-channel field effect transistor) and a first PFET (p-channel field effect transistor), and
wherein the second metal line is electrically coupled to the power supply through a second NFET and a second PFET.

6. The digital circuit of claim 4,
wherein a first cross-section area of the first metal line is constant along the length of the first metal line,
wherein a second cross-section area of the second metal line is constant along the length of the second metal line, and
wherein the first metal line and the second metal line comprise a same material.

7. The digital circuit of claim 4,
wherein each comparing circuit of the N comparing circuits comprises a first comparator and a second comparator corresponding to a column of the N columns,
wherein the first comparator comprises a first input and a second input,
wherein the second comparator comprises a third input and a fourth input,
wherein the second and third inputs are configured to electrically connect to the first tap node of a regular cell of the M×N regular cells of the associated column of the N columns in response to the regular cell being selected for testing,
wherein the first input is electrically connected to the second tap node of the associated reference cell, and
wherein the fourth input is electrically connected to the third tap node of the associated reference cell.

8. The digital circuit of claim 7,
wherein each comparing circuit of the N comparing circuits further comprises a NOR gate,
wherein the NOR gate comprises a fifth input and a sixth input,
wherein a first output of the first comparator is electrically coupled to the fifth input of the NOR gate and
wherein a second output of the second comparator is electrically coupled to the sixth input of the NOR gate.

9. The digital circuit of claim 1, wherein the digital circuit is configured such that only one regular cell of the M×N regular cells in a column of the N columns can be selected for testing at a time.

10. The digital circuit of claim 1, wherein the digital circuit is configured such that regular cells of the M×N regular cells in a row of the M rows can be selected simultaneously for testing.

11. A digital circuit operation method, comprising:
providing (a) M×N regular cells electrically arranged in M rows and N columns, M and N being positive integers, (b) N reference cells corresponding one-to-one to the N columns and (c) N comparing circuits corresponding one-to-one to the N columns,
wherein each regular cell of the M×N regular cells is electrically coupled to a comparing circuit of the N comparing circuits associated with a column in which the regular cell resides,
wherein each reference cell of the N reference cells is electrically coupled to the associated comparing circuit of the N comparing circuits,
wherein each regular cell of the M×N regular cells comprises a first tap node, and
wherein each reference cell of the N reference cells comprises P tap nodes, P being an integer greater than 1:
selecting a regular cell of the M×N regular cells for testing,
using a comparing circuit associated with the regular cell, in response to a first voltage of the first tap node of the regular cell being between two voltages of two tap nodes of the P tap nodes of the associated reference cell to generate a first signal indicating that the regular cell is in good condition; and
using the comparing circuit associated with the regular cell in response to the first voltage of the first tap node of the regular cell not being between the two voltages of the two tap nodes of the P tap nodes of the associated reference cell to generate a second signal indicating that the regular cell is not in good condition.

12. The method of claim 11 further comprising:
providing M×N pass gate circuits corresponding one-to-one to the M×N regular cells; and
using each pass gate circuit of the M×N pass gate circuits to electrically couple the associated regular cell to the associated comparing circuit in response to the associated regular cell being selected for testing.

13. The method of claim 11 further comprising:
providing N MUX circuits corresponding one-to-one to the N columns,
wherein each MUX circuit of the N MUX circuits is electrically coupled to the P tap nodes of the associated reference cell; and
using each MUX circuit of the N MUX circuits to electrically couple two tap nodes of the P tap nodes to the associated comparing circuit at a time.

14. The method of claim 11,
wherein each regular cell of the M×N regular cells comprises a first metal line,
wherein the first tap node of the each regular cell divides the first metal line into a first segment and a second segment,
wherein each reference cell of the N reference cells comprises a second metal line,
wherein P−2,
wherein the P tap nodes comprise a second tap node and a third tap node,
wherein the second and third tap nodes divide the second metal line into a third segment, a fourth segment, and a fifth segment,
wherein the fourth segment is disposed between the third segment and the fifth segment, and
wherein a first length L(R1), a second length L(R2), a third length L(R3), a fourth length L(R4), and a fifth length L(R5) of the first segment, the second segment, the third segment, the fourth segment, and the fifth segment, respectively, are such that
$$\frac{L ( R 3 ) + L ( R 4 )}{L ( R 3 ) + L ( R 4 ) + L ( R 5 )} > \frac{L ( R 1 )}{L ( R 1 ) + ( R 2 )} > \frac{L ( R 3 )}{L ( R 3 ) + L ( R 4 ) + L ( R 5 )} .$$

15. The method of claim 14,
wherein the first metal line of the each regular cell is electrically coupled to a power supply through a first NFET (n-channel field effect transistor) and a first PFET (p-channel field effect transistor), and
wherein the second metal line is electrically coupled to the power supply through a second NFET and a second PFET.

16. The method of claim 14,
wherein a first cross-section area of the first metal line is constant along the length of the first metal line,
wherein a second cross-section area of the second metal line is constant along the length of the second metal line, and
wherein the first metal line and the second metal line comprise a same material.

17. The method of claim 14,
wherein each comparing circuit of the N comparing circuits comprises a first comparator and a second comparator corresponding to a column of the N columns,
wherein the first comparator comprises a first input and a second input,
wherein the second comparator comprises a third input and a fourth input,
wherein the first input is electrically connected to the second tap node of the associated reference cell,
wherein the fourth input is electrically connected to the third tap node of the associated reference cell, and
wherein said selecting the regular cell comprises electrically connecting the first tap node of the regular cell to the second and third inputs of the associated comparing circuit.

18. The method of claim 17,
wherein each comparing circuit of the N comparing circuits further comprises a NOR gate,
wherein the NOR gate comprises a fifth input and a sixth input,
wherein a first output of the first comparator is electrically coupled to the fifth input of the NOR gate,
wherein a second output of the second comparator is electrically coupled to the sixth input of the NOR gate,
wherein said using the comparing circuit to generate the first signal comprises using the NOR gate to generate the first signal, and
wherein said using the comparing circuit to generate the second signal comprises using the NOR gate to generate the second signal.

19. The method of claim 11 wherein said selecting the regular cell comprises not selecting another regular cell of the M×N regular cell in the same column.

20. The method of claim 11 further comprising selecting other regular cells of the M×N regular cells in the same row.
wherein said selecting the regular cell and said selecting the other regular cells are performed simultaneously.
